(19) United States
(12) Patent Application Publication
(10) Pub. No.: US 2002/0094196 A1
(43) Pub. Date: Jul. 18, 2002

(54) Conduction heater for the BOC Edwards Auto 306 evaporator

(76) Inventor: Peter V. Schwartz, San Luis Obispo, CA (US)

Correspondence Address: KNOBBE MARTENS OLSON & BEAR LLP, 620 NEWPORT CENTER DRIVE, SIXTEENTH FLOOR, NEWPORT BEACH, CA, 92660, US

(21) Appl. No.: 10/010,079

(22) Filed: Nov. 9, 2001

Related U.S. Application Data
(60) Provisional application No. 60/247,199, filed on Nov. 9, 2000.

(51) Int. Cl. C23C 14/00

(52) U.S. Cl. 392/389; 392/388

(57) ABSTRACT

A conductive heating element is disclosed for use with an evaporation-type thin film deposition device. The conductive heater selectively heats the sample to be coated without substantially affecting the temperature of the deposition chamber. As a result, lower deposition chamber pressures and higher sample temperatures are attainable.

### CROSS-REFERENCE TO RELATED APPLICATIONS

This application claims priority to U.S. Provisional Application Serial No. 60/247,199, filed Nov. 9, 2000, the disclosure of which is herein incorporated by reference in its entirety.

### BACKGROUND OF THE INVENTION

1. Field of the Invention

The present invention is generally related to thin film deposition devices and specifically to evaporation devices.

2. Description of the Related Art

It is known in the art to deposit a thin film of material on a sample through the use of an evaporation system. In a current version of such a system, the Edwards Auto 306 Evaporation System creates a vacuum in a bell jar through the use of one or more vacuum pumps. The sample is then heated using a radiant heater comprised of a 500 Watt halogen bulb.

The use of radiant heat has disadvantages. In most applications, the radiant heat cannot be used selectively to heat only the sample. Thus, the use of radiant heaters to increase sample temperature also increases the chamber temperature. Since evaporation rate of surface contaminants is exponentially proportional to temperature, the pressure within the chamber is also increased. Lower pressures are desirable to avoid contamination of the evaporator components. The use of radiant heat in this way is also very inefficient. Less energy would be consumed if only the sample was heated.

Additionally, it is occasionally desirable to anneal the surface of some metals in the coating process. Radiant heaters are seldom successful in this application because of the limited maximum attainable temperature. Furthermore, even if a radiant heater, such as a quartz halogen lamp, is capable of heating a sample to the necessary temperature, the process results in unwanted impurities deposited on the sample surface.

Radiant heaters (such as a thin tungsten wire very close to the back of the sample holder) have been used to selectively heat a sample. Radiant heaters have inherent drawbacks in this application. Radiant heaters tend to be delicate and inconvenient; it is difficult to install a halogen lamp in such a way as to only heat the sample. This application also adds to the inefficiency of radiant heaters. A small percentage of the energy output of the radiant heater is transferred to the sample due to reflection. This results in the additional problem of increasing the temperature of the surrounding chamber (the very problem this application attempts to resolve).

### SUMMARY OF THE INVENTION

The present invention is directed to a substrate mount for a thin film deposition system that is heated conductively. It is desirable to provide a sample heater for evaporator-type thin film deposition systems that employs conductive heat transfer. In this way, the sample may be heated without increasing the temperature of the surrounding chamber. The conductive heater will use less energy since 100% of the heat generated by the heater is transferred to the sample. The construction of conductive heaters, being less fragile than radiant lamps, lends itself to easy mounting to the sample. The conductive heaters may be modular, i.e. one-piece “plug-ins”, that further enhance the convenience of using a conductive heating element.

In a first embodiment of the present invention, a sample mount for an evaporator is provided that includes:

(a) a sample mounting base;

(b) a conductive heater block comprising an electrically conductive material; and

(c) a conductive heater positioned in a cavity in the conductive heater block. The evaporator can be of any suitable configuration. An illustrative evaporator that is compatible with the sample mount is manufactured by BOC Edwards under the tradename “EDWARDS AUTO 306 EVAPORATION SYSTEM”. In this application, the sample mount is directly heated by a UHV compatible cartridge heater. In the absence of the sample mount of the present invention, the Auto 306 Evaporator makes use of radiant heating only. The heated sample mount of the present invention makes use of conductive heating, and can be used as a substitute for, or in combination with, the radiant heater.

The sample mounting base and conductive heater block typically have substantially the same coefficients of thermal expansion and more typically are formed from the same material. In one configuration, the thermally conductive material in the conductive heater block has a coefficient of thermal conductivity of at least about 100 W/m° K and more up to copper at about 400 W/m° K. The thermally conductive material could be any of the following, or alloys thereof: copper, aluminum, tungsten, beryllium oxide, iron and mixtures thereof. Copper and silver are best at about 400 W/m° K, but silver is less advantageous than copper because of its softness. Gold has a thermal conductivity of about 300 W/m° K, but is generally not practicable because of cost. Aluminum has a thermal conductivity of about 240 W/m° K and is a viable option. Stainless steel does not work well in this application, but some hardened steels are workable. Iron has a thermal conductivity of about 78 W/m° K. Nickel has a thermal conductivity of about 88 W/m° K. Nickel is also very hard and has a low vapor pressure. Beryllium Oxide may be an excellent alternative with a thermal conductivity of about 250 W/m° K; it is a hard material and has a low vapor pressure. Beryllium does have the disadvantage of being toxic, however. In one configuration, the sample mounting base and conductive heater block are of one-piece (integral) construction.

In one configuration, the block has a yield strength of no more than about 60 MPa and has features to permit the block to deform to clamp the heater. The conductive heater block includes a full cut extending from a surface of the block to the cavity to permit first and second portions of the block positioned on either side of the full cut to clamp the conductive heater and a partial cut extending from a surface of the block towards the cavity to permit the first and second portions of the block to clamp the conductive heater. The f all and partial cuts are parallel to one another, extend the length of the block, and are on adjacent surfaces of the block. To facilitate deformation, the partial cut has a depth and the depth of the partial cut preferably is at least about 0.050 inch for copper and other materials of similar softness. However, for harder materials, the depth of the partial cut may be as small as about 0.030 inch. In this configuration, the cylindrical cavity for receiving the heater is typically off-center relative to the block; that is, the cavity's axis of symmetry of the cavity is located at a distance from an axis of symmetry of the block.

In another configuration, the block has a yield strength of more than about 200 MPa up to about the GPa hardness of hardened steel, and is of a multi-piece construction to provide for heater clamping. The block includes an upper part and a lower part that define a cylindrical cavity therebetween. The upper and lower parts are clamped together by one or more connectors to hold the heater in position.

The heater can be any suitably designed, shaped, and sized conductive heater. In one configuration, the conductive heater includes concentric layers, namely an outer metal layer, a ceramic layer located interiorly of the outer metal layer, a metal coil positioned interiorly of the ceramic layer, and an inner ceramic layer located interiorly of the metal coil. A preferred example is a UHV compatible cartridge heater.

In another embodiment, a method for operating a thin film deposition system is provided. The method includes the steps of:

(a) beginning pumping chamber at room temperature;

(b) radiantly heating a deposition chamber to a first temperature to vaporize undesirable deposits, while pumping them out of the chamber with the pump;

(c) cooling chamber to room temperature leaving surfaces largely free of contamination;

(d) while chamber cools, heating sample with conduction heater to a very high second temperature to free sample of contaminants;

(e) when chamber is cool, evaporating deposition material onto the sample surface.

The sample surface, in step (e) above, is very clean because of the preceding steps. Also, in step (e), the sample may be hot, i.e., heated by the conduction heater, or cold.

In one configuration, the first temperature ranges from about 100° C. to about 200° C., and the second temperature from about 100° C. to about 700° C.

In one configuration, steps (a) and (b) occur simultaneously.

In one configuration, steps (a) and (b) occur before step (c).

In one configuration, the method further includes before step (c) the step of cooling the chamber to ambient temperature.

In one configuration, the chamber pressure in steps (a) and (b) is at least about 10⁻⁶ Torr while the chamber pressure in step (c) is no more than about 10⁻⁷ Torr. Routinely, the chamber pressure in steps (a) and (b) is about 100 times more than a chamber pressure in step (c).

The holder and method can have a number of advantages. Conductive heating, in particular, provides the following advantages:

1) High sample temperature achievable. Radiant heaters can take the sample temperature up to about 300° C. before causing damage to the entire unit. Furthermore, the present 500 W halogen light that presently heats evaporators such as the Auto 306, is only capable of raising the temperature of the sample in front of the light to about 300° C. The conductive sample heater of the present invention can achieve temperatures typically greater than about 700° C. while negligibly raising the temperature of neighboring vacuum components. The ultimate temperature achievable is most likely greater than about 800° C., with the configuration, metals and cartridge heater used.

2) Greater speed in achieving high sample temperatures. While the radiant heater raises the temperature of the sample at about 2.4° C./min between the temperatures of about 100° C. and about 150° C., the direct heating sample mount of the present invention heats at a rate of at least about 35° C./min , more typically at a rate of about 40° C./min.

3) Lower pressures accessible with elevated sample temperature. Directly heating the sample allows the sample to have a high temperature while the surrounding interior components stay cool. This results in less outgassing. For lowest pressures possible, both radiant and direct heaters should be used sequentially. The initial chamber bakeout can be executed with a radiant heater to release surface-bound substances on all interior components. Subsequent sample heating can be done with the direct sample heater, while the rest of the chamber cools. This is possible because the heated sample holder dissipates little heat into the chamber. The sample holder is able to maintain a temperature of about 640° C. while dissipating only about 23 W. We have been able to attain a pressure as low as about 5×10⁻⁸ Torr, and typically no more than about 2×10⁻⁷ mb with the above sample temperatures. These temperatures and pressures are not entirely indicative of the effectiveness of the sample mount of the present invention, however. In a typical UHV apparatus with our heated sample mount, one would expect pressures on the order of about 10⁻¹⁰ Torr, dependant upon how well the pump works and how long the pump is operated. What is more relevant, and impressive, is with the sample mount of the present invention in the Auto 306 evaporator, a pressure of about 10⁻⁷ Torr with a sample temperature of about 700° C. may be achieved within approximately 6 hours.

4) Reduced cooling time. Because the direct heater offers more effective heating potential, it can be used simultaneous with a cooling braid. A cooling braid could be connected from the sample mount to the base plate to expedite cooling after the heater was turned off.

5) Conductive heated sample mount. A radiant heater must heat the entire chamber in order to heat the sample mount. A small, commercially available, cartridge heater can dissipate about 70-80% of its power into the sample being heated at high temperatures, i.e., greater than about 600° C. and may dissipate close to 100% of its power into the sample at lower temperatures. Virtually all of the power goes to heating the cartridge heater, and thus the sample mount. Only a minute amount of heat is radiated directly away from the heater to the outside world, e.g., through the end holes of the sample heater (reference the bright glow as seen in FIG. 12). In order to minimize this loss, the heater and the block/sample holder must be the same temperature. A good thermal connection between the heater and the sample holder is required. In other word, for this to be effective, there must be a very tight connection between the heater's surface and that of the sample mount.

6) Expected commercial applications. Direct sample heating greatly facilitates evaporation, or any other surface processing that require sample temperatures greater than about 300° C.

### BRIEF DESCRIPTION OF THE DRAWINGS

FIG. 1 is an end view of one embodiment of the sample mount of the present invention;

FIG. 2 is a plan view of the embodiment of the sample mount of the present invention shown in FIG. 1;

FIG. 3 is an end view of the sample mount of the present invention shown in FIG. 1 with an integrally mounted thermocouple and associated connector;

FIG. 4 is an end view of an alternative embodiment of the sample mount of the present invention;

FIG. 5 is plan view of the embodiment of the sample mount of the present invention shown in FIG. 4;

FIG. 6 is an exploded, perspective view of one embodiment of the sample mount of the present invention and a heating element;

FIG. 7 is a cross-sectional view of one embodiment of the heating element of the present invention;

FIG. 8 is a schematic view of one embodiment of the evaporation system of the present invention;

FIG. 9 is a back perspective view of an alternative embodiment of the sample mount of the present invention;

FIG. 10 is a front perspective view of the embodiment of FIG. 9 with a sample attached to the sample mount;

FIG. 11A shows the sample mount of FIG. 9 mounted in an evaporator;

FIG. 11B is an end view of the embodiment of the present invention of FIG. 9A;

FIG. 11C is an elevation view of the embodiment of the present invention of FIG. 9B;

FIG. 12 is a back perspective view of the embodiment of FIG. 9 shown at 690° C.; and

FIG. 13 is another back perspective view of the embodiment of FIG. 9.

### DETAILED DESCRIPTION OF THE PREFERRED EMBODIMENT

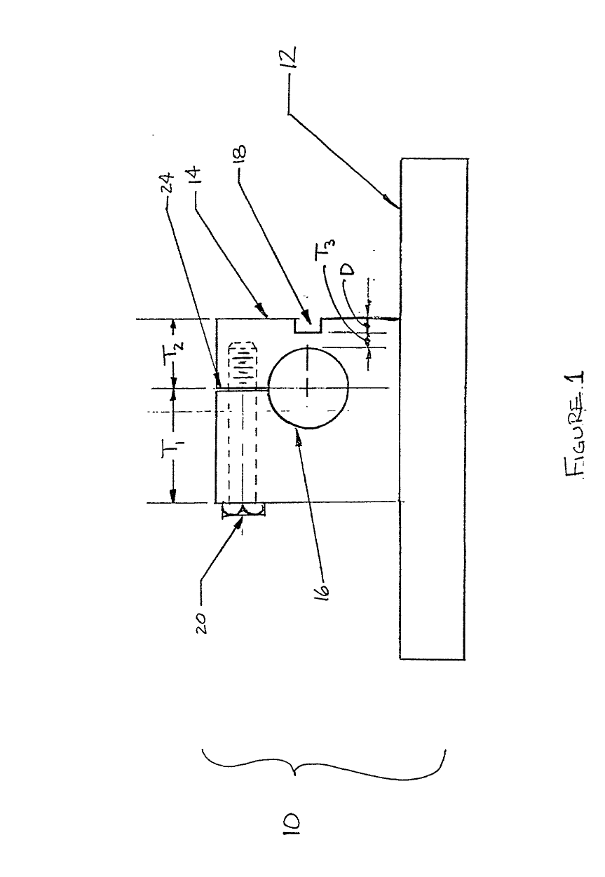

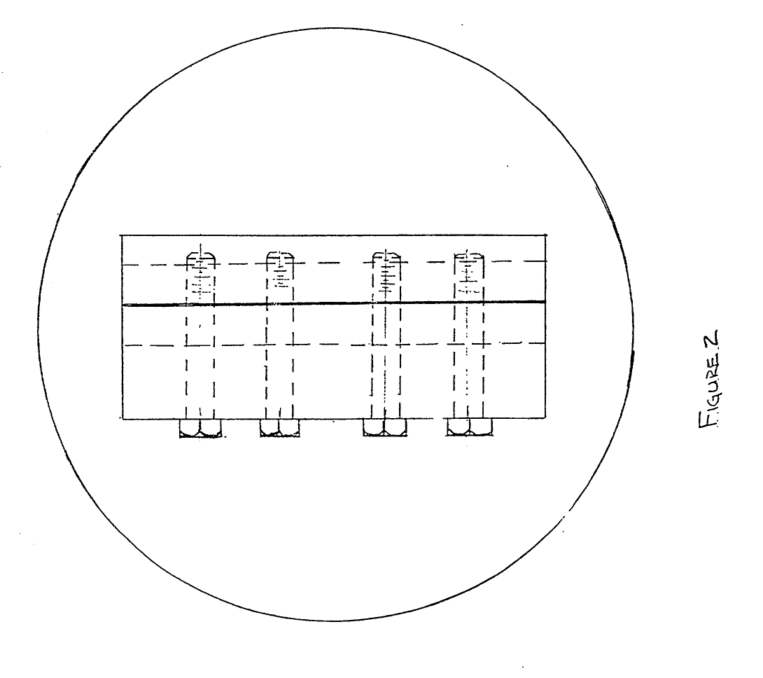

FIG. 1 shows one embodiment of the sample mount of the present invention in an end view. The sample mount 10 comprises a mounting base 12 and a conductive heater block 14. In this embodiment, the mounting base 12 and the heater block 14 are of one-piece construction.

The mounting base 12 may have mounting holes for securing the article to be treated (the sample) to the mounting base. These mounting holes may be tapped for receiving threads or may be drilled to receive a bolt to be secured by a nut.

The conductive heater block 14 has a heating element aperture 16 for receiving a conductive heating element. The placement of the heating element aperture 16 within the heater block 14 may be varied depending on the material selected for the sample mount 10. As shown in FIG. 1, if the sample mount 10 is constructed of copper, which has excellent thermal conductive properties, the heating element aperture 16 can be offset laterally from the center of the heater block 14. This allows more deformation in the smaller dimension of the heater block 14. The more easily the heater block is deformed in this manner, the more surface contact between the heating element and the interior surface of the heating element aperture 16. This in turn results in better thermal conductivity between the heating element and the sample mount 10. Thermal continuity between the heating element and the sample mount 10 is crucial to effective conductive heat transfer. Thus, the heating element must be strongly clamped by the heater block 14. The one-piece construction improves the conductive heat transfer.

Additionally, the conductive heater block 14 may contain a channel 18 along the length, or a portion thereof, of the heater block 14 to add flexibility to, i.e., promote desirable deformation of, the smaller dimension of the heater block 14, and thus, increases thermal conductivity between the conductive heater and the heater block 14. The channel 18 also helps control where bending occurs within the heater block 14. The depth D of the channel 18 is such that the material thickness T3 between the heater aperture 16 and the slot 18 is between 0.030 and 0.060 inch, and more preferably between 0.035 and 0.045 inch.

In this application, the heating element is first inserted into the heater aperture 16. The heating element is then secured in the heater block 14 by heating element securement screws 20. The securement screws 20 are inserted through securement screw holes 22 on one lateral edge of the heater block 14. The securement screw holes 22 extend through the heater block 14 on one lateral side of the slot 24, span the slot 24 and secure into, or through, the heater block 14 on the opposite lateral side of the slot 24. This securement method holds the heating element firmly in place and maintains the necessary thermal conductivity between the heating element and the heater block 14.

The material selection influences the arrangement of the securement screws 20 relative to the heater block 14. If the material chosen for the heater block 14 is copper, a slot 24 may be provided from the heater aperture 16 to a surface of the heater block 14. The slot 24 may be offset laterally from the center of the heater block 14, as described above, such that the dimension T1 from one lateral side of the heater block 14 to the slot 24 is greater than the dimension T2 from the slot 24 to the opposite lateral side of the heater block 14. This offset avoids the possible problem of pulling the screws 20 from the heater block 14 since copper is soft relative to the screws 20. The dimension T3 should be at least approximately 0.040 inch for copper and may be at least approximately 0.030 inch for harder materials. The dimension T1 should be the radius of the aperture 16 plus at least approximately 0.25 inch, i.e., the dimension T1 should be greater than the thickness of the sample mount.

Additionally, the screw holes 22 are threaded only in the heater block 14 in the T2 dimension portion of the block. The screw holes are drilled through, with screw clearance, in the T1 dimension of the block. This helps prevent damage to the block when tightening the securement screws 20 since the yield strength of the securement screws 20 is almost always greater than the yield strength of the copper heater block 14.

With proper insertion of the heating element into the heater block 14, the proper thermal continuity can be maintained. It has been shown that with a tight connection between the heater block and the heating element, the heating element can dissipate nearly 100% of its power into the sample being heated.

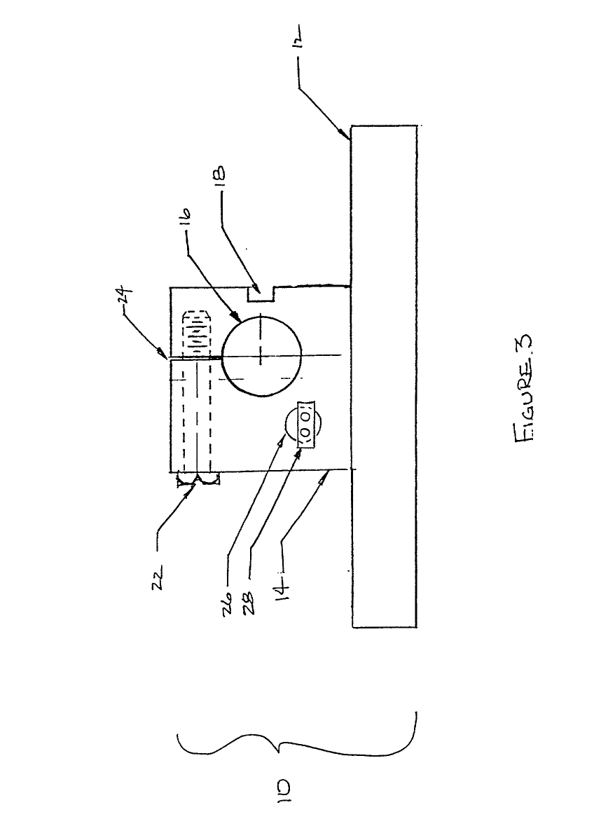

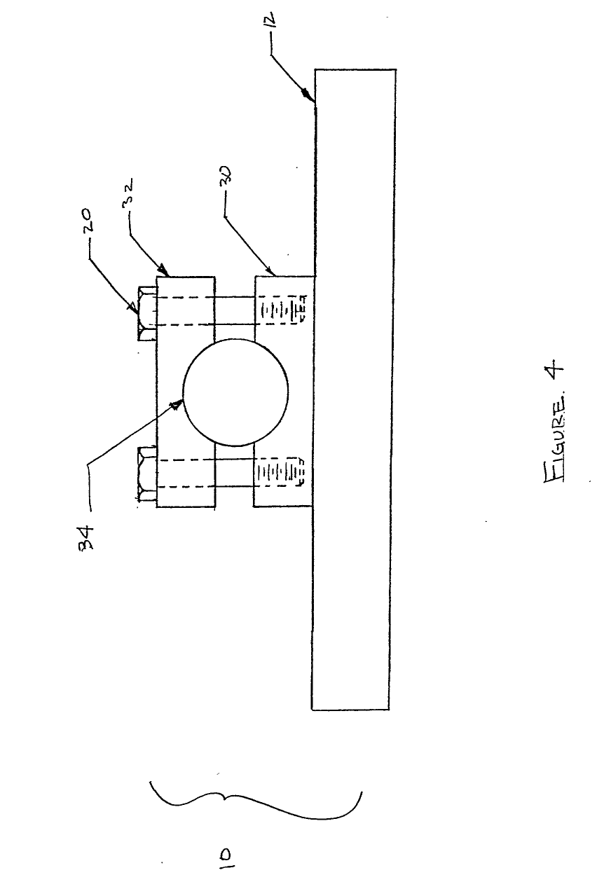

As shown in FIG. 3, the heater block 14 may also contain an integrally mounted thermocouple 26 with attached thermocouple connectors 28. The thermocouple connectors 28 may also be connected to the sample mount 12. This integral mounting allows the thermocouple 26 to be connected with a temperature monitoring device simply by attaching a coupling mechanism to the connectors 28 when the sample mount is installed into the deposition chamber.

As shown in FIG. 4, the heater block 14 may be a two piece construction if hardened steel is the selected material. In this embodiment, the sample holder 10 comprises a mounting base 12, a lower heater block 30 and an upper heater block 32. The heating element 34 is mounted between the lower and upper heater blocks 30 and 32. The lower and upper heater blocks 30 and 32, have corresponding semi-circular channels for mating with the surface of the heating element 34.

The cartridge is secured between the upper heater block 32 and the lower heater block 30 by securement screws 20. The securement screws are inserted through drilled holes in the upper heater block 32. The securement screws 20 then thread into tapped holes in the lower heater block 30. The two piece construction of the heater block is desirable since hardened steel has a tendency to be brittle; thus the steel will crack rather than bend. With the two-piece construction proper conductivity between the sample mount 10 and the cartridge heater 34 can be achieved without damage to the heater blocks 30 and 32. The greater the contact surface between the cartridge heater 34 and the heater blocks 30 and 32, the better the thermal conduction to these blocks. In other words, better heat transfer efficiency is maintained if the legs of the heater blocks 30 and 32 extend as nearly possible to the diameter of the cartridge heater 34.

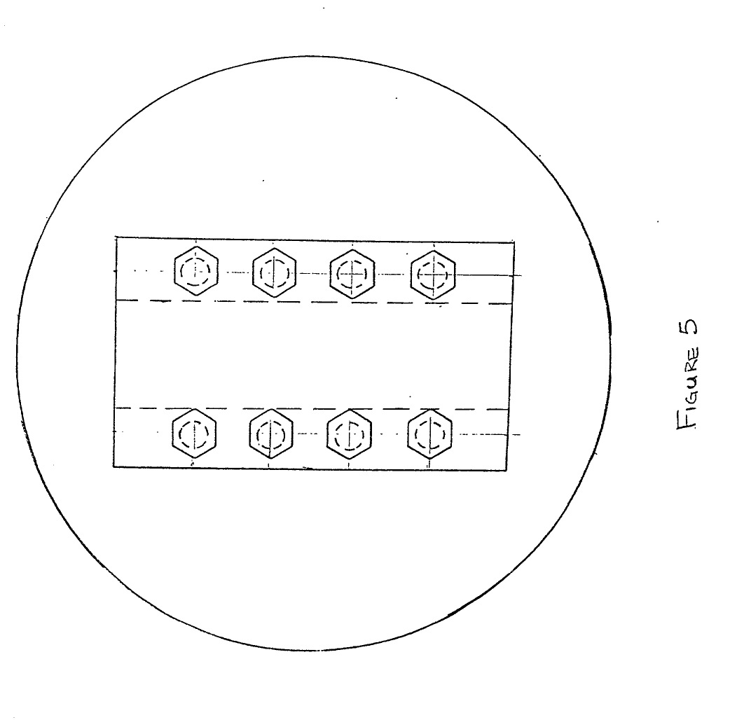

FIG. 6 is a perspective view of the sample mount of FIG. 1 showing the insertion method of the conductive heater. The heating element 34 is inserted into the heater block 14 of the sample holder 10. The heating element 34 has electrical leads 36 for powering the heating element 34. The electrical leads 36 may include a connector (not shown) for quick and simple attachment to the power supply.

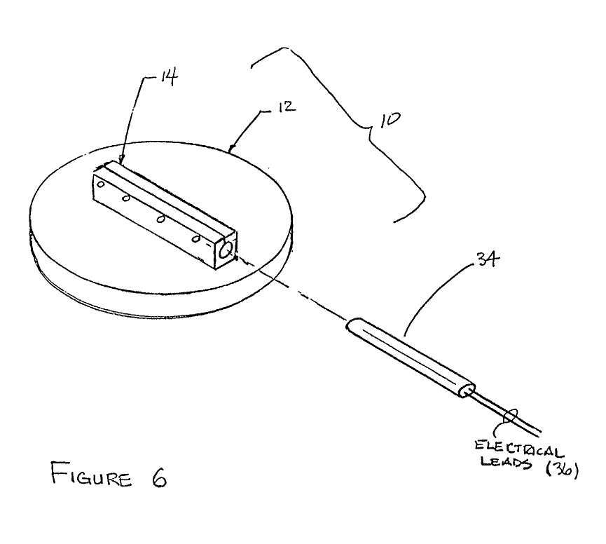

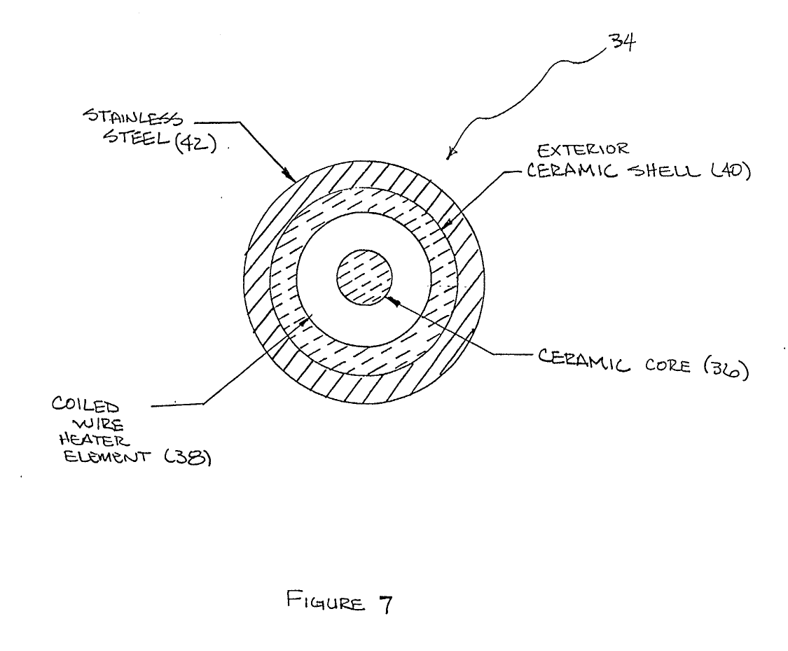

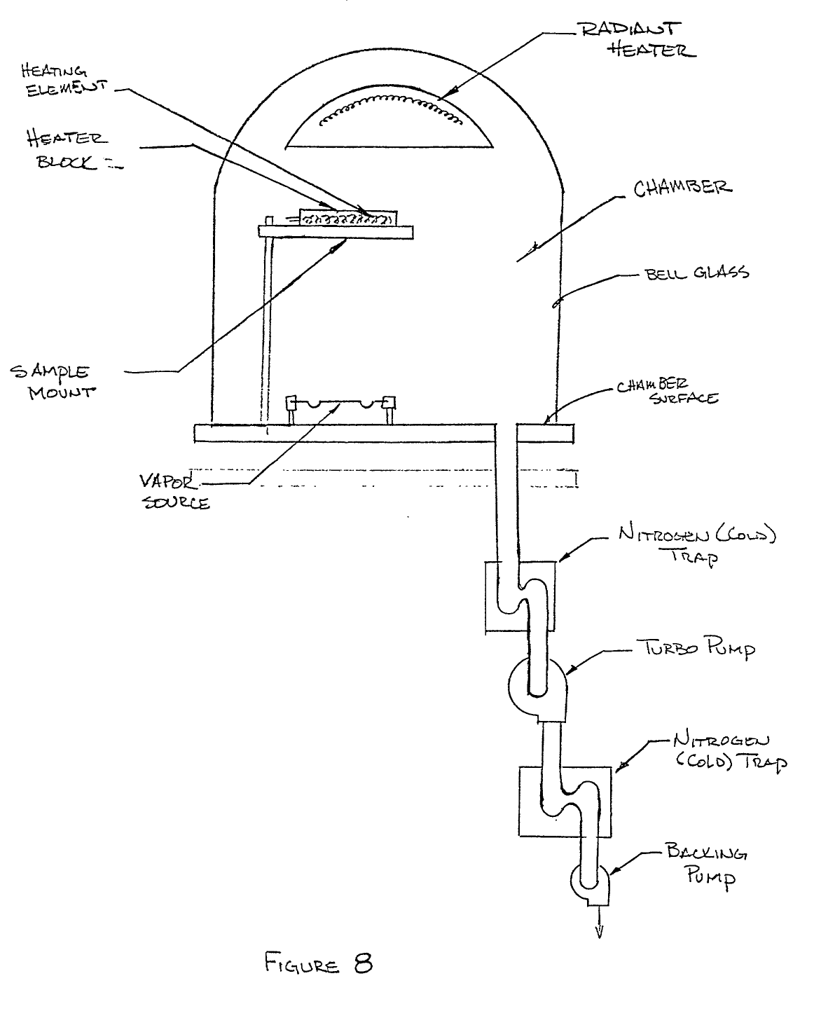

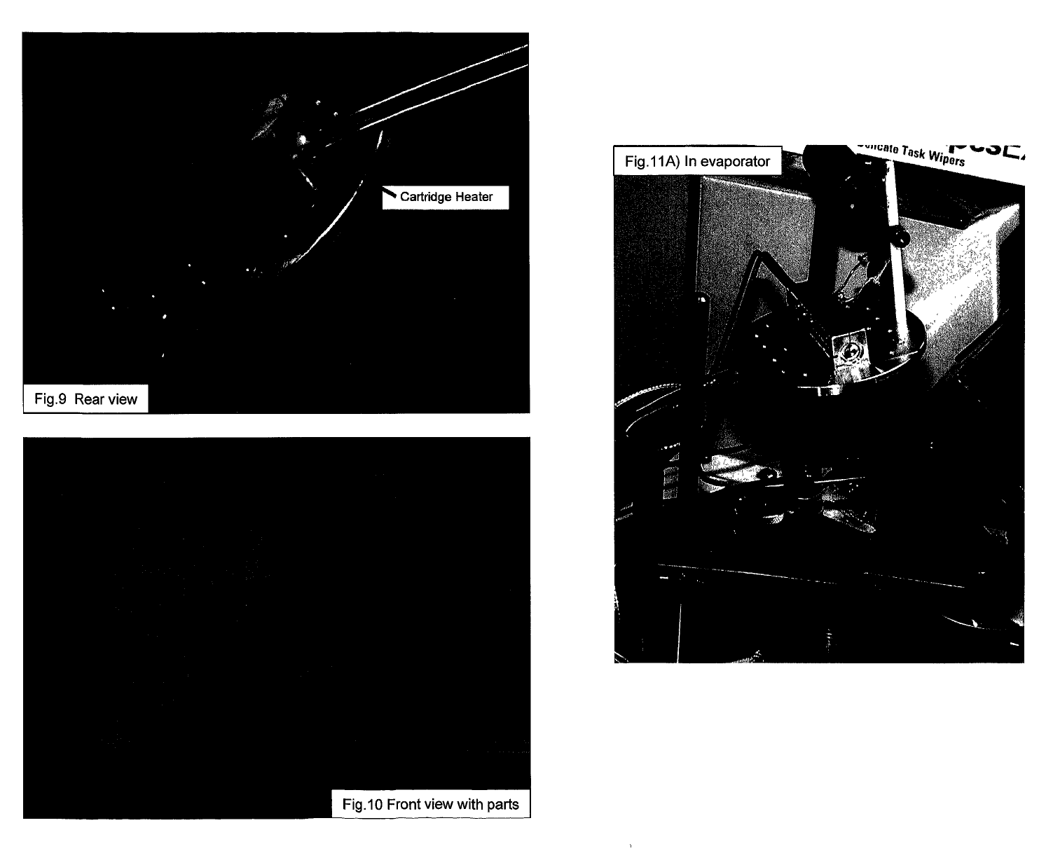

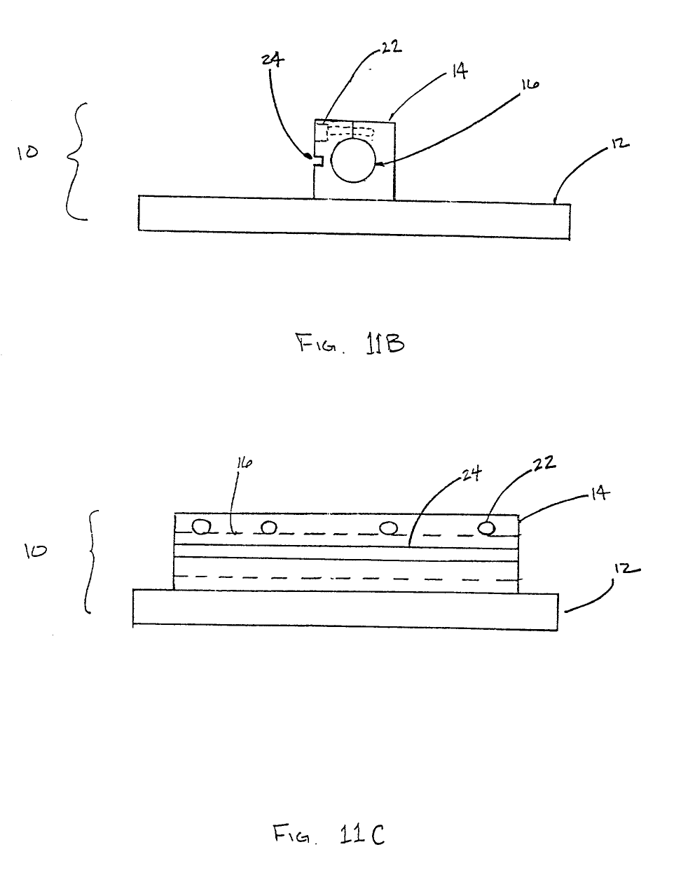

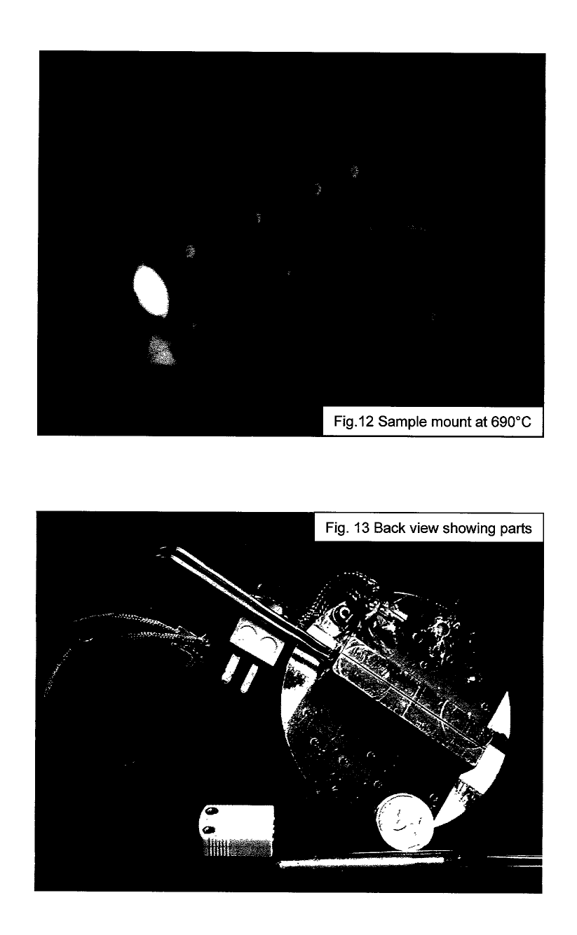

It is anticipated that the heating element 34 may be selected from numerous commercially available cartridge heaters. However, certain applications may warrant specially designed cartridge heaters for use with the sample mount. Additionally, other applications may present the opportunity to incorporate the heating element into the integral design of the sample mount. As shown in FIG. 7, one possible embodiment of the heating element 34 is shown. The heating element 34 has a central ceramic core 36 surrounded by a coiled heating wire 38. The heating wire 38 is surrounded by a exterior ceramic shell 40 which is encapsulated in a stainless steel shell 42.

It is intended that the invention described above would be compatible with, among other things, evaporator-type surface treatment such as thin film deposition. In fact, the initial embodiment of the present invention was designed for use in conjunction with the Edwards Auto 306 Evaporation System.

The present heating system used in the Auto 306 Evaporator makes use of radiant heating only. The present invention may use conductive heating alone, or may use conductive heating in conjunction with traditional radiant heating.

As shown in FIG. 8, the evaporation deposition system may consist of a chamber surface and a bell glass for creating a vacuum chamber. The chamber may contain, among other things, the sample mount with conductive heater; a radiant heater, such as a halogen lamp; the vapor source; and other instrumentation. The other instrumentation is omitted from FIG. 8 to simplify the illustration. A vacuum system is connected to the vacuum chamber for creating the vacuum. The vacuum system of FIG. 8 includes a turbo pump, a backing pump, and cold traps prior to the suction side of each pump. The turbo pump is the primary evacuation device for the chamber. The backing pump may be necessary to enable the turbo pump to attain lower pressures within the chamber. With the turbo pump/backing pump combination, pressures in the range of 5×10⁻⁸ mbar to 5×10⁻⁷ mbar are attainable. The cold traps, or nitrogen traps, prevent the contamination of the chamber environment by pump oils and any dissolved gasses removed during evacuation.

In the preferred method of use, the vacuum chamber is created by placing a bell glass atop the chamber surface to create the vacuum chamber. The pumps are then started to evacuate the chamber. Once the pumps are started, the radiant heater, i.e., halogen lamps, are turned on. After approximately one hour, an equilibrium at a desired high temperature is reached within the chamber. The high temperature and lowered pressure “bake” the contents of the chamber to remove contaminants within the chamber and its contents. Once this equilibrium is reached, the radiant heater is turned off and the chamber is allowed to cool for a desired period, e.g. overnight. As the temperature falls, the pressure within the chamber is also lowered. The pressure within the chamber, once the chamber returns to room temperature, is approximately 5×10⁻⁸ mbar.

Once the chamber is hot, the conductive heater is turned on and remains on as the chamber cools. The conductive heater heats only the sample to be treated. The use of the direct sample heater enables the contents of the chamber, other than the sample, to cool because the direct sample heater dissipates little heat into the chamber. It has been shown, for example, that the sample holder is able to maintain a temperature of 640° C. while dissipating only 23 W. The temperature of the chamber remains at approximately room temperature while the temperature of the sample is elevated to approximately 600° C. At this point, the pressure within the chamber is around 1×10⁻⁷ mbar. The deposition process is now begun.

The direct conductive heating of the sample and the associated ability to maintain the sample temperature while allowing the remainder of the chamber to cool may improve many of the operating characteristics of the evaporator. For example, higher sample temperatures may be obtained, high sample temperatures are reached in less time, lower pressures are accessible with elevated sample temperatures, and cooling time may be reduced.

The known use of a 500 W halogen radiant heater has been shown to heat the sample to a maximum temperature of approximately 300° C. Moreover, attempts to increase the operating temperature have damaged or threatened to damage the entire unit. The conductive sample heater can achieve temperatures far greater than about 600° C. while negligibly raising the temperature of neighboring vacuum components. The ultimate temperature attainable is most likely greater than about 800° C. with the configuration of the present invention. Other configurations may result in still higher temperatures.

The current use of a radiant heater raises the temperature of the sample at approximately 2.4° C./min between the temperatures of about 100° C. and about 150° C. The direct heating of the sample mount can increase the temperature of the sample at about 40° C./min.

As described above, direct heating of the sample allows the sample to have a high temperature while the surrounding interior chamber components remain cool. This results in less outgassing during the evaporation process. Additionally, the reduced chamber temperature enables much lower pressures. The present invention has been shown to attain a pressure of about 2×10⁻⁷ mb with a sample temperature of about 500° C. in less than about 6 hours.

The direct heater increases the temperature of essentially only the sample and sample holder. Thus the mass to be cooled is considerably less than the contents of the entire chamber. It follows that less time is required to cool the sample than the entire chamber. Moreover, the direct heater can be used simultaneously with a cooling braid because the direct heater offers more effective heating potential. The cooling braid is essentially is a construction of at least one piece of copper tubing that provides water to the sample for cooling. Interior channels may be formed within the sample holder and connected at one end of the channel to the supply tubing and at another end to the return tubing. The cooling braid may constantly cool the sample by providing a flow of water to the sample mount even when the heater is operated. In this embodiment, the heater is much more powerful and would “win”, i.e., overcome the cooling of the water when the heater is on. However, the braid would effectively cool the sample mount when the heater is off. Alternatively, the cooling braid may be turned off during the heating cycle and engaged only when cooling is desired after the heater is turn off. In either method, the cooling braid may expedite cooling after the heater is turned off.

The foregoing description of the present invention has been presented for purposes of illustration and description. Furthermore, the description is not intended to limit the invention to the form disclosed herein. Consequently, variations and modifications commensurate with the above teachings, and the skill or knowledge of the relevant art, are within the scope of the present invention. The embodiments described herein are further intended to explain the best mode known for practicing the invention and to enable others skilled in the art to utilize the invention in such, or other, embodiments and with various modifications required by the particular applications or uses of the present invention. It is intended that the appended claims be construed to include alternative embodiments to the extent permitted by the prior art.

What is claimed is:

1. A sample mount for an evaporator, comprising:
(a) a sample mounting base;
(b) a conductive heater block comprising an thermally conductive material; and
(c) a conductive heater positioned in a cavity in the conductive heater block.

2. The sample mount of claim 1, wherein the sample mounting base and conductive heater block are of one-piece construction.

3. The sample mount of claim 1, wherein the thermally conductive material in the conductive heater block has a coefficient of thermal conductivity of at least about 40 W/m° K.

4. The sample mount of claim 1, wherein the thermally conductive material includes one or more of copper and alloys thereof, steel, tungsten, beryllium oxide, iron, and aluminum.

5. The sample mount of claim 1, wherein the conductive heater block includes a full cut extending from a surface of the block to the cavity to permit first and second portions of the block positioned on either side of the full cut to clamp the conductive heater.

6. The sample mount of claim 5, wherein the conductive heater block includes a partial cut extending from a surface of the block towards the cavity to permit the first and second portions of the block to clamp the conductive heater and wherein the block has a yield strength of no more than about 200 MPa.

7. The sample mount of claim 6, wherein the full and partial cuts are parallel to one another and extend the length of the block.

8. The sample mount of claim 6, wherein the partial cut has a depth and the depth of the partial cut is such that the material thickness between the conductive heater and the partial cut ranges from about 0.030 inch to about 0.060 inch.

9. The sample mount of claim 5, wherein the full cut and partial cut are on adjacent surfaces of the block.

10. The sample mount of claim 1, wherein the cavity is cylindrical in shape and the axis of symmetry of the cavity is located at a distance from an axis of symmetry of the block.

11. The sample mount of claim 1, wherein the conductive heater includes an outer metal layer, a ceramic layer located interiorly of the outer metal layer, a metal coil positioned interiorly of the ceramic layer, and an inner ceramic layer located interiorly of the metal coil.

12. The sample mount of claim 1, wherein the block has a yield strength of at least about 200 MPa and includes an upper part and a lower part that define a cylindrical cavity therebetween, the upper and lower parts being clamped together by one or more connectors to hold the heater in position.

13. A method for operating a thin film deposition system, comprising:
(a) radiantly heating a deposition chamber to a first temperature to vaporize undesirable deposits;
(b) while removing the vaporized undesirable deposits using a vacuum pump to form a decontaminated deposition chamber;
(c) conductively heating a substrate in the decontaminated deposition chamber to a second temperature in order to clean, anneal substrate, or to form a thin film on a substrate on the mount, wherein the first temperature is less than the second temperature.

14. The method of claim 13, wherein the first temperature ranges from about 100° C. to about 300° C.

15. The method of claim 13, wherein the second temperature ranges from about 100° C. to about 1000° C.

16. The method of claim 13, wherein steps (a) and (b) occur simultaneously.

17. The method of claim 13, wherein steps (a) and (b) occur before step (c).

18. The method of claim 13, further comprising before step (c) cooling the chamber to ambient temperature.

19. The method of claim 13, wherein in steps (a) and (b) a chamber pressure is at least about 10⁻¹⁰ Torr.

20. The method of claim 13, wherein in steps (c) a chamber pressure is no more than about 10⁻³ Torr.

21. The method of claim 13, wherein a chamber pressure in steps (a) and (b) is at least about 100% more than a chamber pressure in step (c).
